(19) United States
(12) Patent Application Publication
(10) Pub. No.: US 2011/0059402 A1
(43) Pub. Date: Mar. 10, 2011

(54) EXPOSURE METHOD

(76) Inventors: Tsukasa Azuma, Kanagawa (JP); Takashi Sato, Kanagawa (JP)

(21) Appl. No.: 12/857,416

(22) Filed: Aug. 16, 2010

(30) Foreign Application Priority Data
Sep. 10, 2009 (JP) 2009-209678

(51) Int. Cl. G03F 7/004; H01L 21/027

(52) U.S. Cl. 430/312; 430/325

(57) ABSTRACT

According to the embodiments, exposure is performed on a resist on a substrate at a first focus position by using a phase shift mask in which a first light transmitting area and a second light transmitting area are formed adjacently via a light shielding pattern and a phase difference between light transmitting through the first light transmitting area and light transmitting through the second light transmitting area is φ≠π, and exposure is performed on the resist at a second focus position different from the first focus position by using the phase shift mask.

### CROSS-REFERENCE TO RELATED APPLICATIONS

This application is based upon and claims the benefit of priority from the prior Japanese Patent Application No. 2009-209678, filed on Sep. 10, 2009; the entire contents of which are incorporated herein by reference.

### FIELD

The present embodiments typically relate to an exposure method.

### BACKGROUND

In a recent lithography process, it is desired to form a fine pattern below a resolution limit of a state-of-the-art exposure apparatus. For this purpose, for example, a method of exposing a resist layer on a substrate by using a halftone-type phase shift mask is used. In this method, light transmitting patterns with a size of about an exposure wavelength are arranged in a lattice shape with intervals of about the exposure wavelength to be used as a mask. Then, a first exposure by a main peak at a focal point and a second exposure at a position which is shifted forward or backward from the focal point along an optical axis and at which a side peak becomes substantially equal to or larger than the main peak are performed in an overlapping manner on the same resist layer.

However, with this method, because the halftone-type phase shift mask is used, there is a problem that the effect of enhancing the resolution is low. Moreover, there is a problem that only a hole pattern is formed and a line pattern cannot be formed.

### BRIEF DESCRIPTION OF THE DRAWINGS

FIG. 1 is a diagram illustrating a configuration of a Levenson-type phase shift mask;

FIG. 2A and FIG. 2B are diagrams illustrating a relationship between the configuration of the Levenson-type phase shift mask and resist patterns;

FIG. 3 is a diagram for explaining an exposure method according to a present embodiment;

FIG. 4 is a diagram for explaining the exposure method in the case of performing resolution of a 1/2 pitch pattern in three exposure processes; and

FIG. 5A and FIG. 5B are diagrams for explaining movement of a resolution position by using an off-optical-axis illumination.

### DETAILED DESCRIPTION

According to embodiments, exposure is performed on a resist on a substrate at a first focus position by using a phase shift mask in which a first light transmitting area and a second light transmitting area are formed adjacently via a light shielding pattern and a phase difference between light transmitting through the first light transmitting area and light transmitting through the second light transmitting area is φ≠π, and exposure is performed on the resist at a second focus position different from the first focus position by using the phase shift mask.

An exposure method according to the embodiments will be explained below in detail with reference to the accompanying drawings. The present invention is not limited to these embodiments.

In the present embodiments, exposure to resist is performed by using a Levenson-type phase shift mask (Levenson or alternating type phase shift mask) in which a phase of a phase shifter (phase difference) is φ≠π. At this time, exposure is performed twice at different focal points on a mask pattern for a double pitch (2P) formed in the Levenson-type phase shift mask. For example, two exposures of a plus-defocus exposure and a minus-defocus exposure with respect to a focal point (best focus) are performed. Whereby, resist patterns of a pitch (P) are formed, in which an alignment accuracy between masks when performing exposure twice and a pattern alignment accuracy in the case of exposing after shifting by a half pitch are not needed. In other words, the resist pattern is formed by utilizing the fact that a pattern causes displacement in accordance with an arrangement of a phase shifter at a certain defocus value by adjusting dZ=dP/a (dZ is a defocus amount, dP is a pattern displacement amount, and a is a tile of a calibration curve determined in accordance with the phase of the phase shifter).

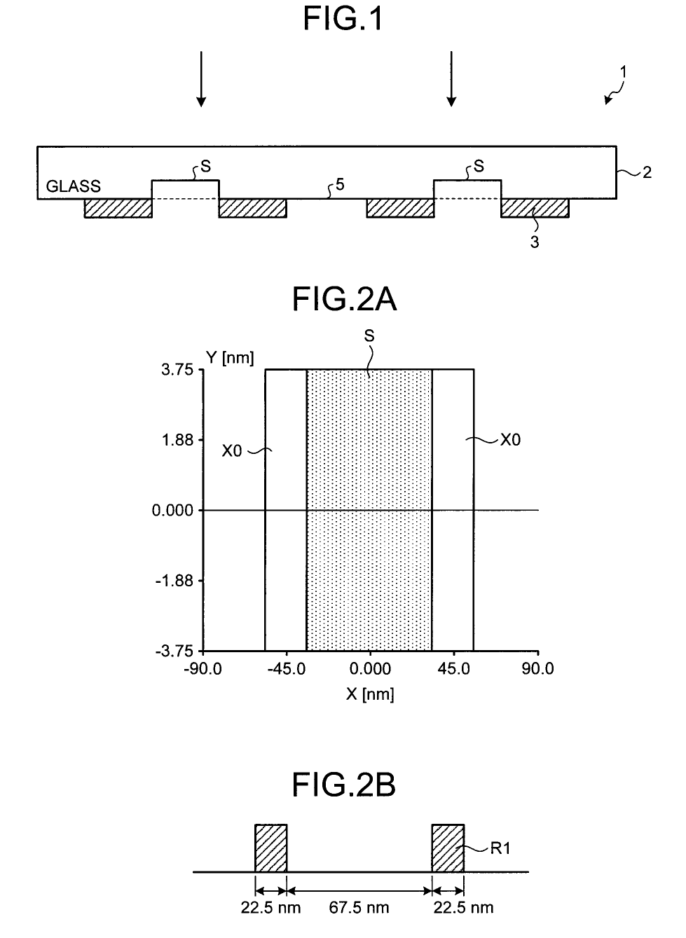

FIG. 1 is a diagram illustrating a configuration of the Levenson-type phase shift mask. FIG. 1 illustrates a cross-sectional configuration in the case of cutting line patterns of a Levenson-type phase shift mask 1 on which line & space is formed along a lateral direction.

The Levenson-type phase shift mask 1 includes a glass substrate 2 and light shielding units (light shielding patterns) 3 such as chrome formed on the back surface of the glass substrate 2. The glass substrate 2 is a substrate for forming the mask pattern and the light shielding unit 3 defines the mask pattern. A plurality of line & space patterns is formed in the Levenson-type phase shift mask 1 and the line patterns correspond to the light shielding units 3. Therefore, when a lithography process is performed by using a positive resist, the mask pattern shape of the light shielding units 3 corresponds to the shape of the resist patterns formed on the substrate such as a wafer.

Among areas (light transmitting area) between the light shielding unit 3 and the light shielding unit 3, a phase shifter S is formed in a predetermined area. The phase shifter S is an area that changes a phase of an exposure light transmitting through the Levenson-type phase shift mask 1. In the Levenson-type phase shift mask 1, the light transmitting areas are formed adjacent to each other via the light shielding unit 3, and the phase shifter S and the light transmitting area other than the phase shifter S are arranged so that a phase difference of lights transmitting through adjacent light transmitting areas becomes φ≠π. The phase shifter S is formed, for example, by grinding the back surface of the glass substrate 2 to a predetermined depth. In the Levenson-type phase shift mask 1 in the present embodiment, the phase shifter S is formed such that a phase φ of the phase shifter becomes, for example, φ=π/2.

When the Levenson-type phase shift mask 1 is set in an exposure apparatus and the exposure apparatus radiates exposure light, the exposure light is radiated onto the front surface side of the Levenson-type phase shift mask 1. This exposure light transmits through the glass substrate 2. The exposure light is shielded at the light shielding unit 3 corresponding to the line pattern. Moreover, the exposure light transmits through the area (space pattern area 5) in which neither the light shielding unit 3 nor the phase shifter S is formed. Furthermore, in the phase shifter S, the phase of the exposure light is changed by φ=π/2. Then, the exposure light whose phase is changed in the phase shifter S and the exposure light that has transmitted through the space pattern area 5 without phase change are radiated onto a wafer on which resist is applied.

In the present embodiment, the exposure process is performed twice on the wafer via the Levenson-type phase shift mask 1 without replacing the Levenson-type phase shift mask 1 set in the exposure apparatus. At this time, the exposure is performed with different focus values in the first exposure process and the second exposure process. Specifically, as an overlapping exposure process on the same substrate at different focus positions, exposure is performed at a first focus position and at a second focus position that is different from the first focus position. Whereby, the relative position between the Levenson-type phase shift mask 1 and the wafer when performing exposure at the first focus position becomes the same as the relative position between the Levenson-type phase shift mask 1 and the wafer when performing exposure at the second focus position. In the first exposure process and the second exposure process, exposure is performed so that an optical image intensity distribution formed on the resist on the wafer has a predetermined period.

Whereby, a predetermined position on the wafer in accordance with each focus value at the time of the exposure process, the phase φ of the phase shifter, and the mask pattern is exposed and is subjected to a development process, so that the resist patterns of the line & space are formed on the wafer.

FIG. 2A and FIG. 2B are diagrams illustrating a relationship between the configuration of the Levenson-type phase shift mask and the resist patterns. FIG. 2A and FIG. 2B illustrate a simulation result (resist pattern shape) of the resist patterns formed by using the Levenson-type phase shift mask. As a simulation model, for example, a Kirchhoff mask is used.

FIG. 2A illustrates a diagram when viewing the mask patterns in the Levenson-type phase shift mask 1 from the upper surface side. FIG. 2B illustrates a top view of the resist patterns formed when the exposure and development processes are performed by using the mask patterns in FIG. 2A. In FIG. 2A, a dimension of an actual mask pattern is not illustrated and a dimension (dimension of the resist pattern formed by using the mask pattern) that is 1/4 times of the mask pattern is illustrated. In the followings, a pattern is hatched in some cases even in the top view.

Mask patterns X0 and X0 that are the light shielding units 3 are formed in the Levenson-type phase shift mask 1. The phase shifter S is formed between the mask pattern X0 and the mask pattern X0.

As an exposure condition of the exposure process using the Levenson-type phase shift mask 1, for example, NA=1.35, an illumination shape is an annular illumination, coherence is 0.3, and a type of polarization is S polarization. As the mask pattern of the Levenson-type phase shift mask 1, the mask pattern is used in which a shape of a resist pattern R1 to be formed is such that a pattern pitch=90 nm, a line width=22.5 nm, and an inter-pattern width=67.5 nm, and the phase of the phase shifter S becomes 90 degrees. As the exposure apparatus, for example, an ArF immersion exposure apparatus is used.

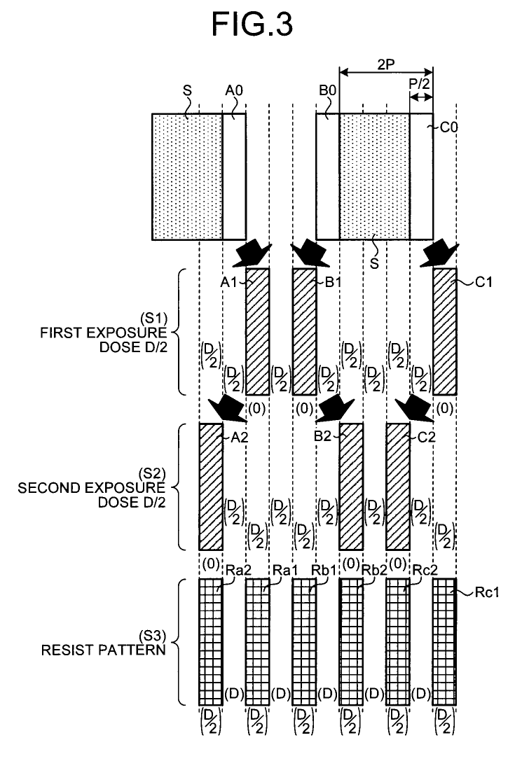

Next, the exposure process is explained in the case of applying the resist pattern exposure method in the present embodiment to the Levenson-type phase shift mask 1. FIG. 3 is a diagram for explaining the exposure method according to the present embodiment. FIG. 3 illustrates a diagram when viewing the Levenson-type phase shift mask 1, the exposure positions onto the wafer, and the resist patterns formed on the wafer from the upper surface side. In the followings, the case is explained in which the positive resist is used as the resist. Moreover, the case is explained in which the phase shifter S of φ=π/2 is used as an example of the phase shifter S.

In the Levenson-type phase shift mask 1, mask patterns A0, B0, C0, and the like that are the line patterns are formed. Moreover, in the Levenson-type phase shift mask 1, the phase shifter S of φ=π/2 is formed between the mask pattern B0 and the mask pattern C0, and the phase shifter S of φ=π/2 is formed between the mask pattern A0 and a not-shown another mask pattern. A space pattern is present between the mask pattern A0 and the mask pattern B0.

The mask patterns A0, B0, and C0 are each the line pattern whose line width is P/2, and the phase shifter S has a dimension width of 3P/2. Therefore, the total width of the mask pattern C0 and the phase shifter S is 2P. In the similar manner, the total width of the mask pattern A0 and the phase shifter S and the total width of the mask pattern B0 and the phase shifter S are each 2P. In other words, in the Levenson-type phase shift mask 1, the mask patterns in which a ratio between the line width and the dimension width of the phase shifter S is 1:3 are formed. Among the areas between the mask patterns, the dimension of the space pattern area (between the mask pattern A0 and the mask pattern B0) in which the phase shifter S is not formed is 3P/2. Therefore, in the Levenson-type phase shift mask 1, the mask patterns are formed, which are obtained by expanding patterns having the line width of P/2 and the pitch (2P) by four times.

In the present embodiment, as the first exposure process (S1), exposure via the Levenson-type phase shift mask 1 is performed with a predetermined plus defocus value (for example, +0.04 μm). An exposure dose D/2 is used in the first exposure process. An exposure dose D is a dose as a reference in the exposure process. As the resist used in the exposure process, resist is used with which the resist pattern does not remain in a portion exposed with the exposure dose D and the resist pattern remains in a portion exposed with the exposure dose D/2. Specifically, the resist is adjusted such that an exposed portion is not dissolved with organic alkaline developer TMAH or the like with the exposure dose D/2 and the exposed portion is dissolved with the exposure dose D to form the space pattern.

With the exposure with the plus defocus value, the mask patterns A0 to C0 are each exposed in a state of being displaced on the opposite side (outer side of the phase shifter S) of the adjacent phase shifter S. Specifically, the mask pattern A0 is exposed at an exposure position A1 that is shifted by P/2 on the right side of the case of exposing with a reference defocus value. The mask pattern B0 is exposed at an exposure position B1 that is shifted by P/2 on the left side of the case of exposing with the reference defocus value, and the mask pattern C0 is exposed at an exposure position C1 that is shifted by P/2 on the right side of the case of exposing with the reference defocus value. Whereby, in the first exposure process, the exposure dose at the exposure positions A1 to C1 becomes 0, and the exposure dose at positions other than the exposure positions A1 to C1 becomes D/2.

Thereafter, as the second exposure process (S2), exposure via the Levenson-type phase shift mask 1 is performed with a predetermined minus defocus value (for example, −0.04 μm). In the second exposure process again, the exposure dose D/2 is used in the similar manner to the first exposure process.

With the exposure with the minus defocus value, the mask patterns A0 to C0 are each exposed in a state of being displaced on the adjacent phase shifter S side (inner side of the phase shifter S). Specifically, the mask pattern A0 is exposed at an exposure position A2 that is shifted by P/2 on the left side of the case of exposing with the reference defocus value. The mask pattern B0 is exposed at the exposure position B2 that is shifted by P/2 on the right side of the case of exposing with the reference defocus value, and the mask pattern C0 is exposed at an exposure position C2 that is shifted by P/2 on the left side of the case of exposing with the reference defocus value. Whereby, in the second exposure process, the exposure dose at the exposure positions A2 to C2 becomes 0, and the exposure dose at positions other than the exposure positions A2 to C2 becomes D/2.

With the first and second exposure processes, the exposure dose at each of the exposure positions A1 to C1 and A2 to C2 becomes D/2, and the exposure dose at positions other than the exposure positions A1 to C1 and A2 to C2 becomes D.

Thereafter, a post-exposure heating process is performed if needed and the development process is further performed, so that the resist pattern is patterned at each of the exposure positions A1 to C1 and A2 to C2 (S3). FIG. 3 illustrates the case where a resist pattern Ra2, a resist pattern Ra1, a resist pattern Rb1, a resist pattern Rb2, a resist pattern Rc2, and a resist pattern Rc1 are formed at the exposure position A2, the exposure position A1, the exposure position B1, the exposure position B2, the exposure position C2, and the exposure position C1, respectively.

Whereby, it becomes possible to transfer the mask patterns in which the line width is P/2 and the pitch is 2P on the wafer onto the wafer as the resist patterns in which the line width is P/2 and the pitch is P. In other words, the mask patterns in which the line width is P/2 and the space pattern width is 3P/2 on the wafer can be transferred onto the wafer as the resist patterns in which the line width is P/2 and the space pattern width is P/2. Therefore, in terms of a pitch pattern resolution that is a ratio between the pitch of the mask patterns and the pitch of the resist patterns, a 1/2 pitch pattern resolution can be realized. A duty ratio that is a ratio between the space pattern width and the line width can be changed to three times.

In FIG. 3, explanation is given for the case of forming the resist patterns having the pitch P; however, the pitch pattern can be made smaller by performing the defocus exposure three times or more. For example, when the resolution of the 1/2 pitch pattern or less is required, the defocus exposure is performed three times or more and the dose at each exposure is adjusted. At this time, exposure is not performed a plurality of times at the same defocus position.

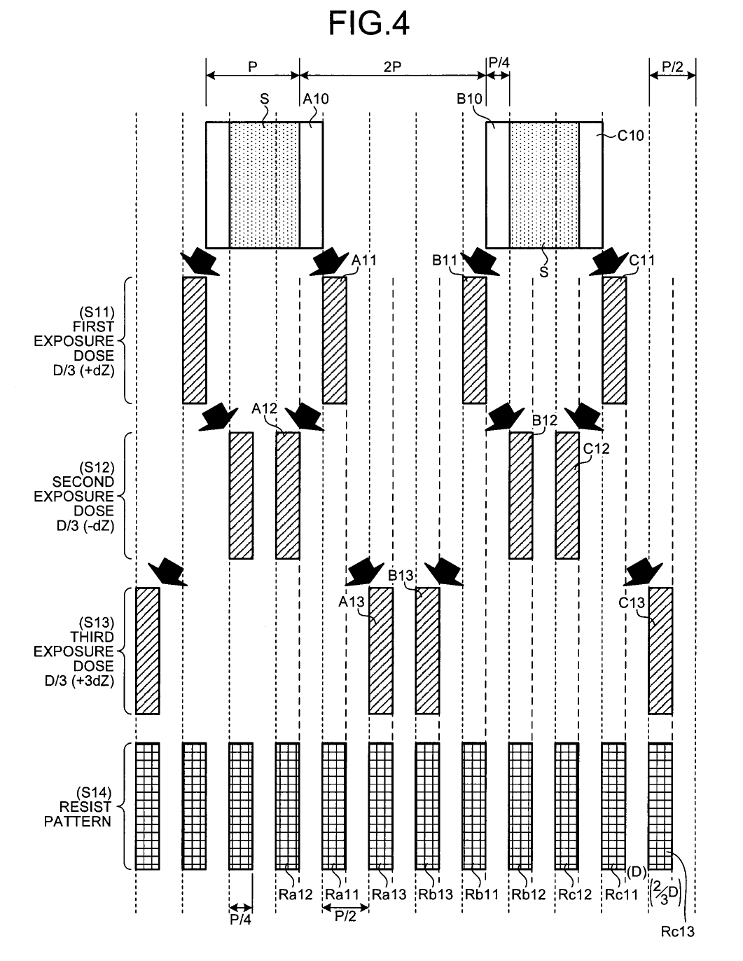

FIG. 4 is a diagram for explaining the exposure method in the case of performing resolution of the 1/2 pitch pattern in three exposure processes. FIG. 4 illustrates a diagram when viewing the Levenson-type phase shift mask 1, the exposure positions onto the wafer, and the resist patterns formed on the wafer from the upper surface side. Among processes explained in FIG. 4, explanation is omitted for the process similar to that explained in FIG. 3.

In the Levenson-type phase shift mask 1 in this example, mask patterns A10, B10, C10, and the like that are the line patterns are formed. Moreover, in the Levenson-type phase shift mask 1, the phase shifter S of φ=π/2 is formed between the mask pattern B10 and the mask pattern C10, and the phase shifter S of φ=π/2 is formed between the mask pattern A10 and another mask pattern. Moreover, the space pattern is present between the mask pattern A10 and the mask pattern B10.

The mask patterns A10, B10, and C10 are each the line pattern whose line width is P/4, and the phase shifter S has a dimension width of 3P/4. Therefore, the total width of the mask pattern C10 and the phase shifter S is P. In the similar manner, the total width of the mask pattern A10 and the phase shifter S and the total width of the mask pattern B10 and the phase shifter S are each P. In other words, in the Levenson-type phase shift mask 1, the mask patterns in which a ratio between the line width and the dimension width of the phase shifter S is 1:3 is formed. Therefore, in the Levenson-type phase shift mask 1, the mask patterns are formed, which are obtained by expanding patterns having the line width of P/4 and the pitch P by four times.

Among the areas between the mask patterns, the dimension of the space pattern area (between the mask pattern A10 and the mask pattern B10) in which the phase shifter S is not formed is 7P/4. Therefore, when the space pattern area is set as a reference, in the Levenson-type phase shift mask 1, the mask patterns are formed, which are obtained by expanding patterns having the line width of P/4 and the pitch P by four times.

In the present embodiment, as the first exposure process (S11), exposure via the Levenson-type phase shift mask 1 is performed with a predetermined plus defocus value (for example, +dZ μm). An exposure dose D/3 is used in the first exposure process. The exposure dose D is a dose as a reference in the exposure process. As the resist used in the exposure process, resist is used with which the resist pattern does not remain in a portion exposed with the exposure dose D and the resist pattern remains in a portion exposed with the exposure dose 2D/3.

With the exposure with the defocus value of +dZ μm, the mask patterns A10 to C10 are each exposed in a state of being displaced on the opposite side (outer side of the phase shifter S) of the adjacent phase shifter S. Specifically, the mask pattern A10 is exposed at an exposure position A11 that is shifted by P/4 on the right side of the case of exposing with the reference defocus value. The mask pattern B10 is exposed at an exposure position B11 that is shifted by P/4 on the left side of the case of exposing with the reference defocus value, and the mask pattern C10 is exposed at an exposure position C11 that is shifted by P/4 on the right side of the case of exposing with the reference defocus value. Whereby, in the first exposure process, the exposure dose at the exposure positions A11 to C11 becomes 0, and the exposure dose at positions other than the exposure positions A11 to C11 becomes D/3.

Thereafter, as the second exposure process (S12), exposure via the Levenson-type phase shift mask 1 is performed with a predetermined minus defocus value (for example, −dZ μm). In the second exposure process again, the exposure dose D/3 is used in the similar manner to the first exposure process.

With the exposure with the defocus value of −dZ μm, the mask patterns A10 to C10 are each exposed in a state of being displaced on the adjacent phase shifter S side (inner side of the phase shifter S). Specifically, the mask pattern A10 is exposed at an exposure position A12 that is shifted by P/4 on the left side of the case of exposing with the reference defocus value. The mask pattern B10 is exposed at the exposure position B12 that is shifted by P/4 on the right side of the case of exposing with the reference defocus value, and the mask pattern C10 is exposed at an exposure position C12 that is shifted by P/4 on the left side of the case of exposing with the reference defocus value. Whereby, in the second exposure process, the exposure dose at the exposure positions A12 to C12 becomes 0, and the exposure dose at positions other than the exposure positions A12 to C12 becomes D/3.

Moreover, as the third exposure process (S13), exposure via the Levenson-type phase shift mask 1 is performed with a predetermined plus defocus value (for example, +3 dZ μm) (a second plus defocus value or a second minus defocus value). In the third exposure process again, the exposure dose D/3 is used in the similar manner to the first exposure process.

With the exposure with the defocus value of +3 dZ μm, the mask patterns A10 to C10 are each exposed in a state of being displaced on the opposite side (outer side of the phase shifter S) of the adjacent phase shifter S. Specifically, the mask pattern A10 is exposed at an exposure position A13 that is shifted by 3P/4 on the right side of the case of exposing with the reference defocus value. The mask pattern B10 is exposed at an exposure position B13 that is shifted by 3P/4 on the left side of the case of exposing with the reference defocus value, and the mask pattern C10 is exposed at an exposure position C13 that is shifted by 3P/4 on the right side of the case of exposing with the reference defocus value. In other words, in the third exposure process, the exposure dose at the exposure positions A13 to C13 becomes 0, and the exposure dose at positions other than the exposure positions A13 to C13 becomes D/3.

With the first to third exposure processes, the exposure dose at each of the exposure positions A1 to C1, A2 to C2, and A3 to C3 becomes 2D/3, and the exposure dose at positions other than the exposure positions A1 to C1, A2 to C2, and A3 to C3 becomes D.

Thereafter, a post-exposure heating process is performed if needed and the development process is further performed, so that the resist pattern is patterned at each of the exposure positions A11 to C11, A12 to C12, and A13 to C13 (S14). Whereby, a resist pattern Ra12, a resist pattern Ra11, and a resist pattern Ra13 are formed at the exposure position A12, the exposure position A11, and the exposure position A13, respectively. Moreover, a resist pattern Rb13, a resist pattern Rb11, and a resist pattern Rb12 are formed at the exposure position B13, the exposure position B11, and the exposure position B12, respectively. Furthermore, a resist pattern Rc12, a resist pattern Rc11, and a resist pattern Rc13 are formed at the exposure position C12, the exposure position C11, and the exposure position C13, respectively.

Whereby, it becomes possible to transfer the mask patterns in which the line width is P/4 and the pitch is 2P on the wafer onto the wafer as the resist patterns (1/2 pitch pattern resolution) in which the line width is P/4 and the pitch is P. In this manner, when the phase of the phase shifter S is φ≠π, the pattern resolution position can be moved in accordance with the defocus amount.

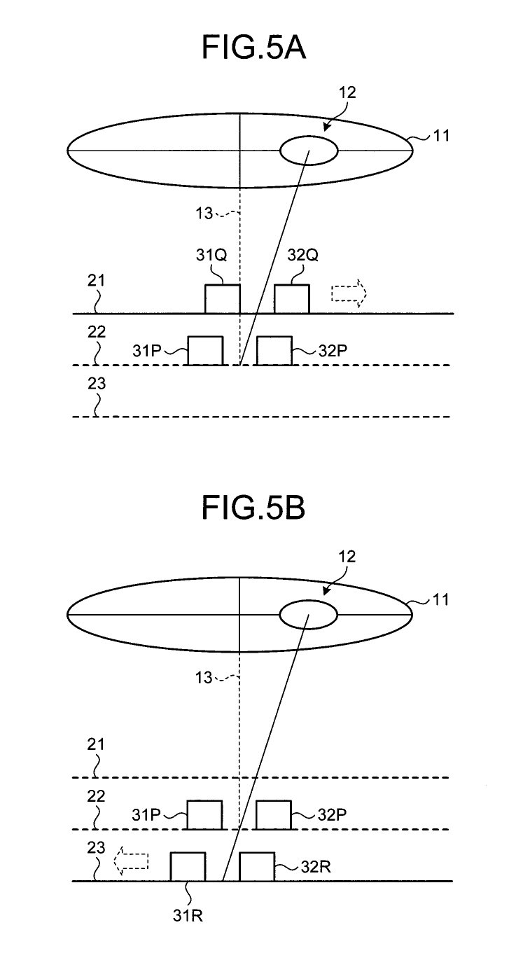

When a monopole illumination is used as an off-optical-axis illumination, a resolution position (resist pattern forming position) on the resist can be shifted. FIG. 5A and FIG. 5B are diagrams for explaining movement of the resolution position by using the off-optical-axis illumination. When a monopole illumination 12 is used as the off-optical-axis illumination, exposure light radiation to the mask is performed via an aperture 11 in which a hole is opened outside an optical axis 13. When exposure is performed by using the monopole illumination 12, on a plus defocus surface 21, the resist patterns are shifted on the right side of the case of exposing on a best focus surface 22. Moreover, on a minus defocus surface 23, the resist patterns are shifted on the left side of the case of exposing on the best focus surface 22.

As shown in FIG. 5A or FIG. 5B, resist patterns 31P and 32P are formed by performing exposure on the best focus surface 22. As shown in FIG. 5A, when exposure is performed on the plus defocus surface 21, resist patterns 31Q and 32Q are formed at positions that are on the right side of the case of exposing on the best focus surface 22. Moreover, as shown in FIG. 5B, when exposure is performed on the minus defocus surface 23, resist patterns 31R and 32R are formed at positions that are on the left side of the case of exposing on the best focus surface 22.

Explanation is given for the case of applying the off-optical-axis illumination to the exposure method explained in FIG. 3. For example, the exposure positions A1 to C1 are shifted by P/8 on the right side of the case of FIG. 3 by performing the first exposure process on the plus defocus surface 21. Moreover, the exposure positions A2 to C2 are shifted by P/8 on the left side of the case of FIG. 3 by performing the second exposure process on the minus defocus surface 23. Whereby, the space between the resist pattern Rb1 corresponding to the exposure position B1 and the resist pattern Rb2 corresponding to the exposure position B2 can be made P/4.

Moreover, when the pitch of the Levenson-type phase shift mask 1 is 2P and the line width of the mask patterns A0 to C0 is equal to or less than P/2 (for example, P/4), the space interval can be narrowed without the resist pattern Rb1 colliding with the resist pattern Rb2 even if the resist pattern forming position is moved by the off-optical-axis illumination.

The off-optical-axis illumination can be applied to the exposure method explained in FIG. 4. For example, when the pitch of the resist patterns on the wafer is P and a displacement amount dP is dP<P/2, a resist pattern resolution (equal interval L/S pattern of the half pitch P/2) with equal intervals cannot be resolved. In such a case, the displacement amount dP can be adjusted to dP≧P/2 by utilizing a two-beam interference by the off-optical-axis illumination such as the monopole illumination. In this manner, the pattern pitch and the duty ratio can be easily adjusted by applying the off-optical-axis illumination to the defocus exposure explained in FIG. 3 and FIG. 4.

The exposure process using the defocus exposure explained in FIG. 3 and FIG. 4 is performed, for example, for each layer of a wafer process. Specifically, exposure using the plus defocus and the minus defocus is performed on the wafer a plurality of times, and thereafter the wafer is developed to form the resist patterns on the wafer. Then, a film on a lower layer side is etched with the resist patterns as a mask. Whereby, an actual pattern is formed on the wafer. When manufacturing a semiconductor device (for example, a CMOS device), the above defocus exposure, development process, etching process, and the like are repeated for each layer.

In the present embodiment, explanation is given for the case where the phase of the phase shifter is φ=π/2; however, the phase of the phase shifter can be any value so long as φ≠π. Moreover, in the present embodiment, explanation is given for the case where the pitch pattern resolution and the duty ratio of the resist patterns are adjusted by exposure using the defocus; however, the resist pattern forming position and the space pattern position can be adjusted by exposure using the defocus. Furthermore, the resolution position on the resist is determined by the defocus value and the phase of the phase shifter, so that it is sufficient to set the defocus value and the phase of the phase shifter in accordance with the position at which the exposure light needs to be resolved.

Moreover, in the present embodiment, the exposure dose for one exposure process is set to D/2 and D/3 in the second exposure process and the third exposure process, respectively; however, for these exposure doses, a distribution of each exposure dose for one exposure process may be changed in accordance with a resist material, a process, an illumination condition, and a mask.

Furthermore, in the present embodiment, explanation is given for the case of performing the exposure process twice or three times on the wafer without replacing the Levenson-type phase shift mask 1 set in the exposure apparatus; however, the second exposure process can be performed after replacing (after resetting) the Levenson-type phase shift mask 1 set in the exposure apparatus in the first exposure process. Moreover, the third exposure process can be performed after replacing the Levenson-type phase shift mask 1 set in the exposure apparatus in the second exposure process.

In this manner, according to the present embodiment, because the resist patterns are formed by using shift of a transfer position by the defocus, an alignment accuracy at the exposure is not needed, so that fine resist patterns can be formed at low process cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A exposure method comprising:
performing exposure on a resist on a substrate at a first focus position by using a phase shift mask in which a first light transmitting area and a second light transmitting area are formed adjacently via a light shielding pattern and a phase difference between light transmitting through the first light transmitting area and light transmitting through the second light transmitting area is φ≠π; and
performing exposure on the resist at a second focus position different from the first focus position by using the phase shift mask.

2. The exposure method according to claim 1, wherein a relative position between the phase shift mask and the substrate at the performing exposure at the first focus position and a relative position between the phase shift mask and the substrate at the performing exposure at the second focus position are same.

3. The exposure method according to claim 1, wherein an optical image intensity distribution formed on the resist has a period at the performing exposure at the first focus position and at the performing exposure at the second focus position.

4. The exposure method according to claim 1, wherein
the performing exposure at the first focus position includes performing exposure at a focus position at which a value obtained by dividing a displacement amount of a resist pattern formed on the substrate by a tilt of a calibration curve determined in accordance with the phase difference becomes the first focus position, and
the performing exposure at the second focus position includes performing exposure at a focus position at which a value obtained by dividing a displacement amount of a resist pattern formed on the substrate by a tilt of a calibration curve determined in accordance with the phase difference becomes the second focus position.

5. The exposure method according to claim 1, wherein the performing exposure at the first focus position or the performing exposure at the second focus position includes performing exposure by using an off-optical-axis illumination of a monopole.

6. The exposure method according to claim 1, wherein each of the performing exposure at the first focus position and the performing exposure at the second focus position includes performing exposure with an exposure dose in accordance with at least one of a resist material, a process, an illumination condition, and the phase shift mask.

7. The exposure method according to claim 1, wherein each of the performing exposure at the first focus position and the performing exposure at the second focus position includes performing exposure with an exposure dose that is a half of a best exposure dose used when forming a pattern on the resist on the substrate by one exposure.

8. The exposure method according to claim 1, wherein after the performing exposure at the first focus position, the exposure at the second focus position is performed by using the phase shift mask without replacing the phase shift mask used at the exposure at the first focus position.

9. The exposure method according to claim 5, wherein
the first focus position is a position that is shifted by a predetermined position from a best focus position used when forming a pattern on the resist on the substrate by one exposure, and
the second focus position is a position that is shifted by a predetermined position from the best focus position in a direction opposite to the first focus position.

10. A manufacturing method of a semiconductor device, wherein the semiconductor device is manufactured by using the exposure method described in claim 1.

11. An exposure method comprising:
performing exposure on a resist on a substrate at a first focus position by using a phase shift mask in which a first light transmitting area and a second light transmitting area are formed adjacently via a light shielding pattern and a phase difference between light transmitting through the first light transmitting area and light transmitting through the second light transmitting area is φ≠π;
performing exposure on the resist at a second focus position different from the first focus position by using the phase shift mask; and
performing exposure on the resist at a third focus position different from both of the first focus position and the second focus position by using the phase shift mask.

12. The exposure method according to claim 11, wherein a relative position between the phase shift mask and the substrate at the performing exposure at the first focus position, a relative position between the phase shift mask and the substrate at the performing exposure at the second focus position, and a relative position between the phase shift mask and the substrate at the performing exposure at the third focus position are same.

13. The exposure method according to claim 11, wherein an optical image intensity distribution formed on the resist has a period at the performing exposure at the first focus position, at the performing exposure at the second focus position, and at the performing exposure at the third focus position.

14. The exposure method according to claim 11, wherein the performing exposure at the first focus position includes performing exposure at a focus position at which a value obtained by dividing a displacement amount of a resist pattern formed on the substrate by a tilt of a calibration curve determined in accordance with the phase difference becomes the first focus position,
the performing exposure at the second focus position includes performing exposure at a focus position at which a value obtained by dividing a displacement amount of a resist pattern formed on the substrate by a tilt of a calibration curve determined in accordance with the phase difference becomes the second focus position, and
the performing exposure at the third focus position includes performing exposure at a focus position at which a value obtained by dividing a displacement amount of a resist pattern formed on the substrate by a tilt of a calibration curve determined in accordance with the phase difference becomes the third focus position.

15. The exposure method according to claim 11, wherein the performing exposure at the first focus position, the performing exposure at the second focus position, or the performing exposure at the third focus position includes performing exposure by using an off-optical-axis illumination of a monopole.

16. The exposure method according to claim 11, wherein each of the performing exposure at the first focus position, the performing exposure at the second focus position, and the performing exposure at the third focus position includes performing exposure with an exposure dose in accordance with at least one of a resist material, a process, an illumination condition, and the phase shift mask.

17. The exposure method according to claim 11, wherein each of the performing exposure at the first focus position, the performing exposure at the second focus position, and the performing exposure at the third focus position includes performing exposure with an exposure dose that is one third of a best exposure dose used when forming a pattern on the resist on the substrate by one exposure.

18. The exposure method according to claim 11, wherein
after the performing exposure at the first focus position, the exposure at the second focus position is performed by using the phase shift mask without replacing the phase shift mask used at the exposure at the first focus position, and
after the performing exposure at the second focus position, the exposure at the third focus position is performed by using the phase shift mask without replacing the phase shift mask used at the exposure at the second focus position.

19. The exposure method according to claim 15, wherein
the first focus position is a position that is shifted by a predetermined position from a best focus position used when forming a pattern on the resist on the substrate by one exposure, and
the second focus position is a position that is shifted by a predetermined position from the best focus position in a direction opposite to the first focus position.

20. A manufacturing method of a semiconductor device, wherein the semiconductor device is manufactured by using the exposure method described in claim 11.
